(19) United States
(12) Patent Application Publication
(10) Pub. No.: US 2015/0062842 A1
(43) Pub. Date: Mar. 5, 2015

(54) ELEMENT SUBSTRATE, DISPLAY APPARATUS AND MANUFACTURING METHOD OF ELEMENT SUBSTRATE

(71) Applicant: InnoLux Corporation, Miao-Li County (TW)

(72) Inventors: Chi-Che TSAI, Miao-Li County (TW); Hui-Chen HSU, Miao-Li County (TW); Wei-Yen WU, Miao-Li County (TW); Wei-Yun CHANG, Miao-Li County (TW)

(21) Appl. No.: 14/456,376

(22) Filed: Aug. 11, 2014

(30) Foreign Application Priority Data
Aug. 30, 2013 (TW) 102131278

(51) Int. Cl. H05K 1/02; H05K 3/46; H05K 3/00; H05K 1/03

(52) U.S. Cl. CPC H05K 1/028; H05K 1/0353; H05K 3/4691; H05K 3/007; H05K 2201/10128
USPC 361/750; 361/749; 156/306.6; 156/289; 156/247

(57) ABSTRACT

An element substrate comprises a flexible substrate, an element layer, a buffer layer and an interface layer. The element layer is disposed on the flexible substrate. The buffer layer is disposed on the flexible substrate. The buffer layer and the element layer are disposed on the opposite sides of the flexible substrate. The interface layer is disposed between the flexible substrate and the buffer layer and includes partial material of both of the flexible substrate and the buffer layer. A display apparatus including the element substrate and a manufacturing method of the element substrate are disclosed.

### CROSS REFERENCE TO RELATED APPLICATIONS

This Non-provisional application claims priority under 35 U.S.C. §119(a) on Patent Application No(s). 102131278 filed in Taiwan, Republic of China on Aug. 30, 2013, the entire contents of which are hereby incorporated by reference.

### BACKGROUND OF THE INVENTION

1. Field of Invention

The invention relates to an element substrate, a display apparatus and a manufacturing method of the element substrate and, in particular, to a flexible element substrate, a display apparatus and a manufacturing method of the flexible element substrate.

2. Related Art

With the progress of technologies, display apparatuses have been widely applied to various kinds of fields. Especially, liquid crystal display (LCD) apparatuses, having advantages such as compact structure, low power consumption, less weight and less radiation, gradually take the place of cathode ray tube (CRT) display apparatuses and are widely applied to various electronic products, such as mobile phones, portable multimedia apparatuses, notebook computers, pad computers and other display apparatuses.

A conventional liquid crystal display (LCD) apparatus mainly includes an LCD panel. The LCD panel mainly includes a thin film transistor (TFT) substrate, a color filter (CF) substrate and a liquid crystal layer disposed between the two substrates. The CF substrate, the TFT substrate and the LC layer form a plurality of pixels disposed in an array. When the light passes through the LCD panel, the all pixels can display colors forming images accordingly. With regard to the future development of the LCD apparatus and OLED display apparatus, the industry expects that the conventional glass substrate can be replaced by the plastic substrate and the TFT elements, electrodes and capacitors can be made on the plastic substrate so as to bring the light, flexible, shatter-proof and shock-proof characteristics.

However, the rigidity of the plastic substrate is scarcely comparable to the glass substrate, so it can not be directly applied to the production line of the TFT elements. Accordingly, the current manner is putting a plastic substrate on a rigid carrier plate (e.g. a glass substrate) and then using the same manufacturing process and equipment as applied to the glass substrate to manufacture the TFT elements or other electronic elements. Nevertheless, an adhesive is required to temporarily stick the plastic substrate on the rigid carrier plate before making the TFT elements, and then a separation is required between the rigid carrier plate and the TFT substrate including the plastic substrate and the TFT elements to bring out the TFT substrate.

Because no proper adhesive can be currently applied in the conventional art, the manufacturing process for making the TFT elements on the plastic substrate just can be implemented by a low temperature process. However, the TFT elements made by a low temperature process will be given bad electric property. For example, the carrier mobility of the channel layer of the TFT is slower so as to result in a bad yield rate. Nevertheless, no proper adhesive can be applied when the TFT elements are made by a high temperature process, although the elements can be made capable of better electric property.

### SUMMARY OF THE INVENTION

In view of the foregoing subject, an objective of the invention is to provide an element substrate, a display apparatus and a manufacturing method of the element substrate that have high heat-resistant property so as to be suitable for the high temperature process so that the element substrate and the display apparatus can be made with better electric property and yield rate.

To achieve the above objective, an element substrate according to the invention comprises a flexible substrate, an element layer, a buffer layer and an interface layer. The element layer is disposed on the flexible substrate. The buffer layer is disposed on the flexible substrate. The buffer layer and the element layer are disposed on the opposite sides of the flexible substrate. The interface layer is disposed between the flexible substrate and the buffer layer and includes partial material of both of the flexible substrate and the buffer layer. The interface layer is formed by a heat treatment process.

To achieve the above objective, a display apparatus according to the invention comprises an element substrate including a flexible substrate, an element layer, a buffer layer and an interface layer. The element layer is disposed on the flexible substrate. The buffer layer is disposed on the flexible substrate. The buffer layer and the element layer are disposed on the opposite sides of the flexible substrate. The interface layer is disposed between the flexible substrate and the buffer layer and includes partial material of both of the flexible substrate and the buffer layer. The interface layer is formed by a heat treatment process.

To achieve the above objective, a manufacturing method of an element substrate according to the invention comprising steps of: providing a rigid carrier plate; forming a buffer layer on the rigid carrier plate; forming a flexible substrate on the buffer layer; implementing a heat treatment process to form an interface layer between the flexible substrate and the buffer layer; and forming an element layer on the flexible substrate.

In one embodiment, the flexible substrate includes organic polymer material.

In one embodiment, the buffer layer includes polymer material of polyimide (PI), acrylic or polysiloxane.

In one embodiment, the interface layer is formed by an interpenetrating polymer network (IPN) generated after the heat treatment process with a subsequent cooling.

In one embodiment, the element substrate further comprises a de-bonding layer disposed on the buffer layer.

In one embodiment, the element substrate is a thin film transistor (TFT) substrate, a color filter (CF) substrate, an organic light-emitting diode (OLED) substrate or a touch substrate.

In one embodiment, before the step of forming the buffer layer, the manufacturing method further comprises a step of: forming a de-bonding layer on the rigid carrier plate.

In one embodiment, the manufacturing method further comprises a step of: separating the de-bonding layer from the buffer layer to obtain the element substrate including the element layer, the flexible substrate, the interface layer and the buffer layer.

In one embodiment, the manufacturing method further comprises a step of: separating the de-bonding layer from the rigid carrier plate to obtain the element substrate including the element layer, the flexible substrate, the interface layer, the buffer layer and the de-bonding layer.

In one embodiment, the manufacturing method further comprises a step of: separating the buffer layer from the rigid carrier plate to obtain the element substrate including the element layer, the flexible substrate, the interface layer and the buffer layer.

In one embodiment, before the step of forming the buffer layer wherein the de-bonding layer has a first surface facing the rigid carrier plate and a second surface which is opposite to the first surface and includes a first part and a second part surrounding the first part, the manufacturing method further comprises a step of: controlling the adhesion of the second surface of the de-bonding layer to make the adhesion of the first part lower than that of the second part.

In one embodiment, before the step of forming the buffer layer wherein the de-bonding layer has a first surface facing the rigid carrier plate and a second surface opposite to the first surface, the manufacturing method further comprises a step of: controlling the adhesions of the first and second surfaces of the de-bonding layer to make the adhesion of the second surface lower than that of the first surface.

In one embodiment, before the step of forming the buffer layer wherein the de-bonding layer has a first surface facing the rigid carrier plate and a second surface opposite to the first surface, the manufacturing method further comprises a step of: controlling the adhesions of the first and second surfaces of the de-bonding layer to make the adhesion of the first surface lower than that of the second surface.

In one embodiment, before the step of forming the buffer layer wherein the rigid carrier plate has a surface including a first part and a second part surrounding the first part, the manufacturing method further comprises a step of: controlling the adhesion of the surface of the rigid carrier plate to make the adhesion of the first part lower than that of the second part.

As mentioned above, in the element substrate, the display apparatus and the manufacturing method of the element substrate of the invention, the element substrate includes a flexible substrate, an element layer, a buffer layer and an interface layer, and the interface layer is formed between the flexible substrate and the buffer layer by a heat treatment process. Thereby, in comparison with the prior art, the invention is not limited to the type of the adhesive material and is capable of high heat-resistant property so as to be suitable for the high temperature process. Besides, the IPN phenomenon of the interface layer can make a better adhesion between the flexible substrate and the buffer layer, and therefore the electronic elements of the element substrate and the display apparatus can be made by a high temperature process so that the element substrate and the display apparatus can have better electric property and yield rate.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic flow chart of a manufacturing method of an element substrate according to an embodiment of the invention;

FIGS. 2A to 2I are schematic diagrams of the manufacturing method of the element substrate according to the first embodiment of the invention;

FIG. 2J is a schematic diagram showing the IPN phenomenon;

FIGS. 3A to 3C are schematic diagrams of the manufacturing method of the element substrate according to the second embodiment of the invention;

FIGS. 4A to 4B are schematic diagrams of the manufacturing method of the element substrate according to the third embodiment of the invention;

FIG. 5 is a schematic flow chart of a manufacturing method of an element substrate according to another embodiment of the invention;

FIGS. 6A to 6D are schematic diagrams of the manufacturing method of the element substrate according to the fourth embodiment of the invention;

FIG. 7A is a schematic sectional diagram of the element substrate before the de-bonding;

FIG. 7B is a schematic enlarged diagram of a region in FIG. 7A;

FIG. 7C schematically shows the SEM image of the structure of FIG. 2F where the flexible substrate is removed by an external force; and

FIG. 7D schematically shows the SEM image of the buffer layer, the de-bonding layer and the rigid carrier plate which are not processed by heat treatment.

### DETAILED DESCRIPTION OF THE INVENTION

The present invention will be apparent from the following detailed description, which proceeds with reference to the accompanying drawings, wherein the same references relate to the same elements.

As below, the element substrate and the display apparatus including the element substrate can be obtained by the clear illustration of the manufacturing method of the element substrate.

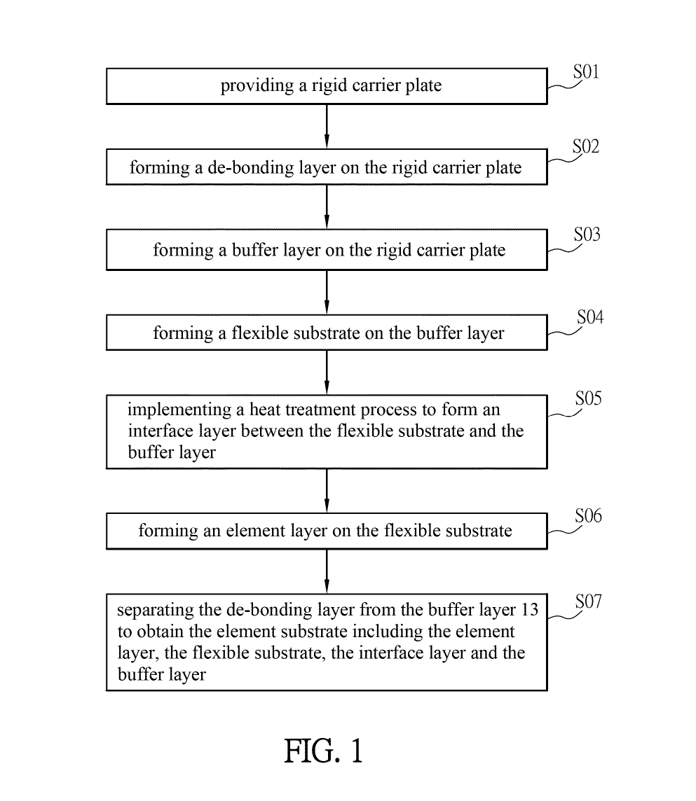

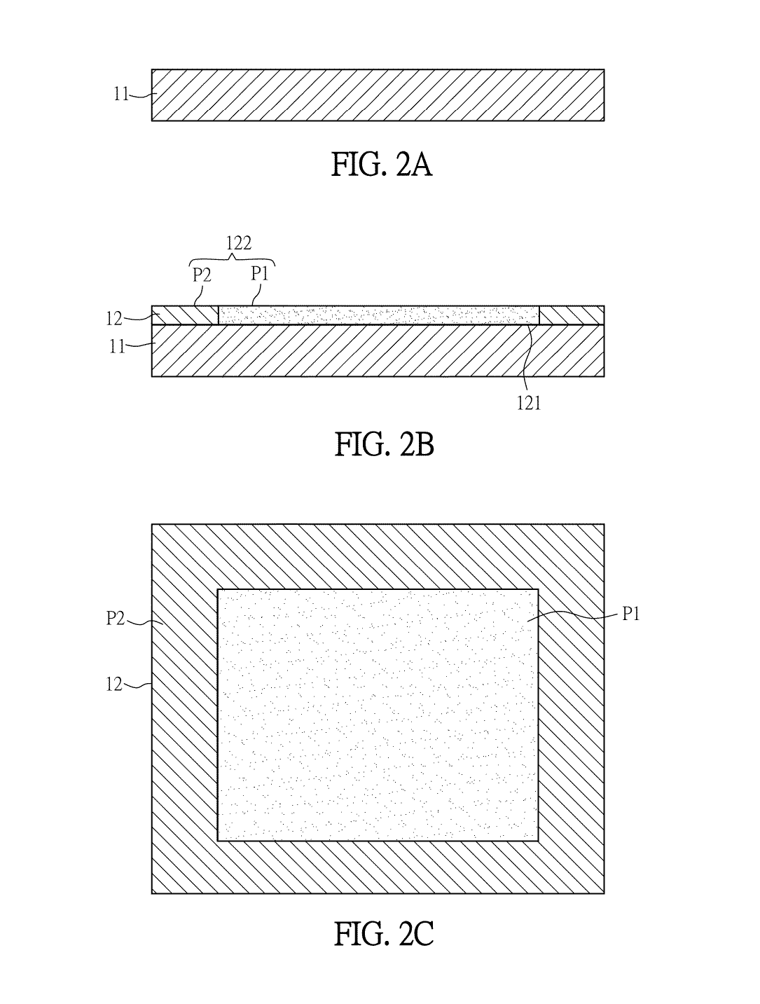

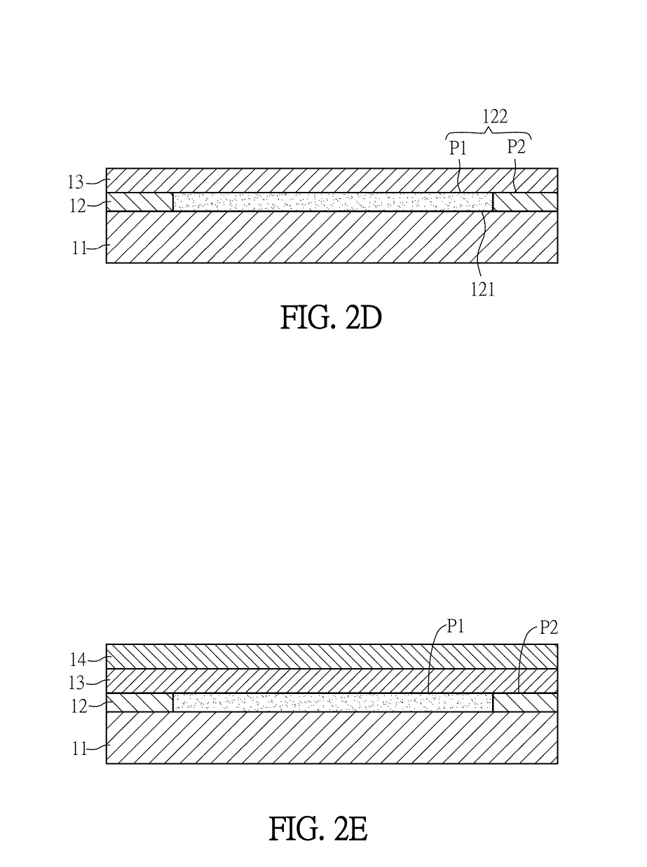

FIG. 1 is a schematic flow chart of a manufacturing method of an element substrate according to an embodiment of the invention, and FIGS. 2A to 2I are schematic diagrams of the manufacturing method of the element substrate according to the first embodiment of the invention.

As shown in FIG. 1, the manufacturing method of the element substrate includes the steps S01 to S07.

First, as shown in FIGS. 1 and 2A, the step S01 is providing a rigid carrier plate 11. Herein for example, the rigid carrier plate 11 is a glass plate, metal plate, fiberglass plate, thick plastic plate, or metal/organic composite plate.

As shown in FIG. 2B (side view) and FIG. 2C (top view of FIG. 2B), the step S02 is forming a de-bonding layer 12 on the rigid carrier plate 11. One of the surfaces of the de-bonding layer 12 is used as the separation interface between the element substrate 1 and the rigid carrier plate 11. In this embodiment, the de-bonding layer 12 can be formed on the rigid carrier plate 11 by the method of spin coating, spray coating or slit coating, so that the de-bonding layer 12 substantially have the same area as the rigid carrier plate 11. The de-bonding layer 12 has a first surface 121 and a second surface 122 opposite to the first surface 121, and the first surface 121 faces the rigid carrier plate 11. The second surface 122 includes a first part P1 and a second part P2 surrounding the first part P1. The area of the first part P1 is greater than or equal to that of the element substrate. The material of the de-bonding layer 12 can include polysiloxane, polyimide (PI), polyamic acid (PAA) or fluoro-polymer for example. In this embodiment, the de-bonding layer 12 includes polysiloxane material for example.

After forming the de-bonding layer 12 and before forming the buffer layer in the step S03, the manufacturing method can further include a step of controlling the adhesion of the second surface 122 of the de-bonding layer 12 to make the adhesion of the first part P1 of the second surface 122 lower than that of the second part P2. The higher adhesion of the second part P2 can firmly fix the substrate to the carrier plate during the process, and the lower adhesion of the first part P1 can be applied to the separation interface between the substrate and the carrier plate. As an embodiment, the property of the second surface 122 of the de-bonding layer 12 is modified by UV illumination or plasma bombardment (e.g. the functional groups of the surface are broken or oxidized to change the adhesion), so that the adhesion of the first part P1 is lower than that of the second part P2. In other words, the adhesion of the second surface 122 is patterned.

Then, as shown in FIG. 2D, the step S03 is forming a buffer layer 13 on the rigid carrier plate 11. In this embodiment, the buffer layer 13 also can be formed on the rigid carrier plate 11 and the de-bonding layer 12 by the method of spin coating, spray coating or slit coating. In a top view, the buffer layer 13, the de-bonding layer 12 and the rigid carrier plate 11 approximately have the same size. The material of the buffer layer 13 can include PI, polyamic acid (PAA), acrylic, polysiloxane or other organic or inorganic polymers for example. Herein, the buffer layer 13 includes PI material for example.

Then, as shown in FIG. 2E, the step S04 is forming a flexible substrate 14 on the buffer layer 13. Herein, the flexible substrate 14 is a flexible film and attached to the buffer layer 13 as a lamination structure through a rolling wheel. The flexible substrate 14 includes organic polymer material, which is also thermoplastic material, such as PI, polyethylene (PE), polyvinylchloride (PVC), PS, acrylic, fluoro-polymer, polyester, or nylon. In this embodiment, the flexible substrate 14 includes PI material for example.

Then, as shown in FIG. 2F, the step S05 is implementing a heat treatment process to form an interface layer 15 between the flexible substrate 14 and the buffer layer 13. In this embodiment, since the flexible substrate 14 and the buffer layer 13 are both PI-contained material, the temperature of the heat treatment process is about between 300° C. and 500° C., and is 400° C. herein for example. Nevertheless, the temperature of the heat treatment may be different according to different material. For example, when the flexible substrate 14 and the buffer layer 13 include PI and acrylic material, the temperature of the heat treatment may be lower than 200° C. After the heat treatment process and a subsequent cooling, an interpenetrating polymer network (IPN) phenomenon will occur between the flexible substrate 14 and the buffer layer 13 to form an interface layer 15.

FIG. 2J is a schematic diagram showing the IPN phenomenon. The IPN phenomenon means two polymer materials (left and middle patterns in FIG. 2J) are bonded to each other by van der Waals' force or hydrogen bond. In this embodiment, because the temperature 400° C. of the heat treatment is closer to or even higher than one of the glass transition temperatures (Tg) of the flexible substrate 14 and the buffer layer 13, the polymer chain (network) of the flexible substrate 14 and the buffer layer 13 will partially dissolve and interpenetrate at their connection interface to form an interface layer 15 having higher adhesion by the IPN phenomenon (right pattern in FIG. 2J), and therefore the interface layer 15 includes partial material of the flexible substrate 14 and partial material of the buffer layer 13.

As shown in FIG. 2G, the step S06 is forming an element layer 16 on the flexible substrate 14. The buffer layer 13 and the element layer 16 are disposed on the opposite sides of the flexible substrate 14. In this embodiment, a high temperature process is implemented to make the elements of the TFT substrate on the flexible substrate 14 to form an element layer 16. Herein, the element layer 16 can include electronic elements such as TFTs, capacitors, conductive layers, transparent electrodes. In other embodiments, the element layer 16 may include a filter layer, a black matrix (BM), a transparent electrode, etc. for making a color filter substrate; the element layer 16 may include TFTs, light-emitting diodes, etc. for making an OLED substrate; or the element layer 16 may include a patterned transparent electrode for making a touch substrate. Therefore, the element substrate 1 made by the manufacturing method of the element substrate of the invention is not limited to a TFT substrate, a CF substrate, an OLED substrate or a touch substrate.

As shown in FIGS. 2H and 2I, the step S07 is separating the de-bonding layer 12 from the buffer layer 13 to obtain the element substrate 1 including the element layer 16, the flexible substrate 14, the interface layer 15 and the buffer layer 13. To be noted, the property of the second surface 122 of the de-bonding layer 12 is modified after the step S02, so that the adhesion of the first part P1 of the second surface 122 is lower than that of the second part P2. So, when the cutting is implemented as shown in FIG. 2H along two cutting lines C which are at the edge of the element substrate 1 and go deep into the de-bonding layer 12, the element substrate 1 as shown in FIG. 2I can be obtained by the separation between the buffer layer 13 and the de-bonding layer 12 at the first part P1.

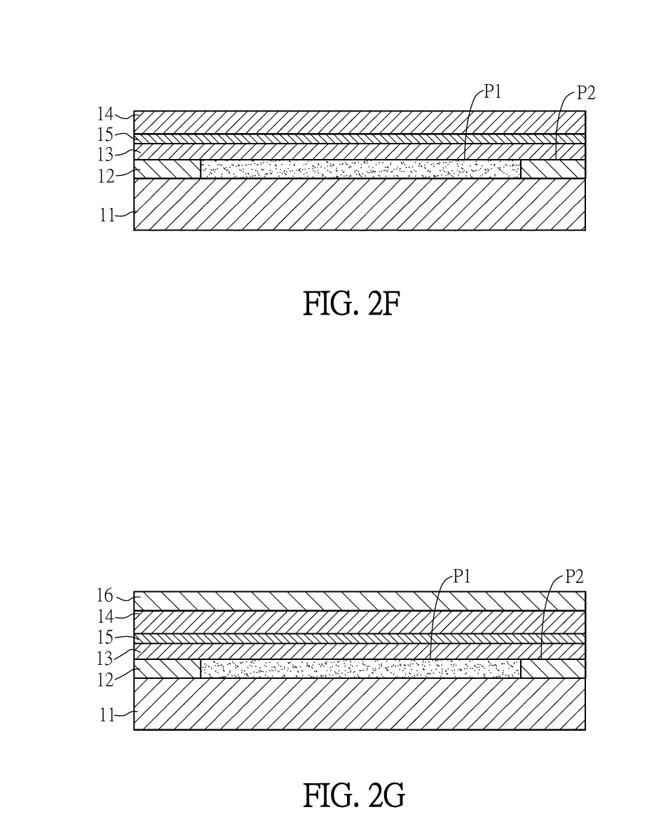

FIGS. 3A to 3C are schematic diagrams of the manufacturing method of the element substrate according to the second embodiment of the invention.

Mainly different from the first embodiment, the de-bonding layer 12 of this embodiment is formed and patterned on the rigid carrier plate 11 as shown in FIGS. 3A and 3B, so that the de-bonding layer 12 is located on the central portion of the rigid carrier plate 11 instead of on the entire corresponding surface of the rigid carrier plate 11. The area of the de-bonding layer 12 is greater than or equal to that of the obtained element substrate, and is less than the area of the rigid carrier plate 11.

In FIG. 3A, the de-bonding layer 12 also has a first surface 121 and a second surface 122 opposite to the first surface 121, and the first surface 121 faces the rigid carrier plate 11. Besides, in this embodiment, the de-bonding layer 12 is controlled so that the adhesion of the second surface 122 can be lower than that of the first surface 121. In other words, the adhesion of the first surface 121 of the de-bonding layer 12 is greater than that of the second surface 122. Moreover, since the de-bonding layer 12 is just formed on the central portion of the rigid carrier plate 11, the buffer layer 13 formed in the step S03 as shown in FIG. 3C is not only located on the de-bonding layer 12 but also surrounds and covers the de-bonding layer 12, and also directly contacts the rigid carrier plate 11.

In the de-bonding process of the step S07, like the first embodiment, because the adhesion of the first surface 121 is greater than that of the second surface 122, the element substrate 1 can be obtained by separating the buffer layer 13 from the de-bonding layer 12 with the second surface 122 (referring to FIGS. 2H and 2I), and the element substrate 1 also includes the element layer 16, the flexible substrate 14, the interface layer 15 and the buffer layer 13.

Since the other technical features and processes of the manufacturing method of the element substrate of the second embodiment can be comprehended by referring to the first embodiment, they are not described here for conciseness.

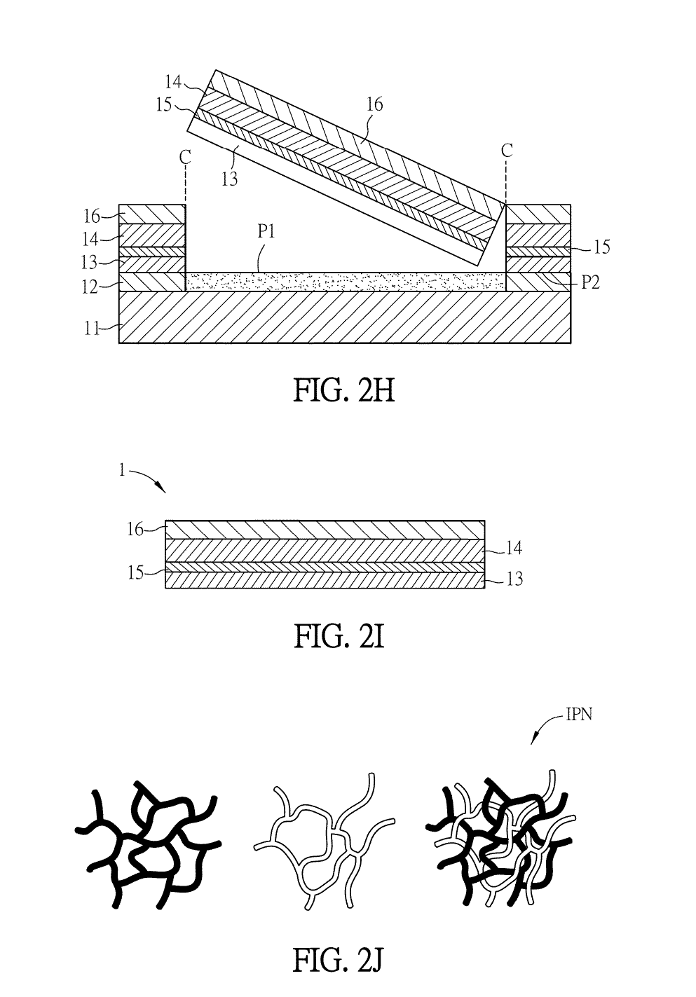

FIGS. 4A to 4B are schematic diagrams of the manufacturing method of the element substrate according to the third embodiment of the invention.

The de-bonding layer 12 of the third embodiment also has a first surface 121 and a second surface 122 opposite to the first surface 121, and the first surface 121 faces the rigid carrier plate 11. In this embodiment, the adhesions of the first and second surfaces 121 and 122 also need to be controlled. However, mainly different from the second embodiment, the adhesions of the first and second surfaces 121 and 122a are controlled so that the first surface 121 can have a lower adhesion than the second surface 122. In other words, the adhesion of the first surface 121 is less than that of the second surface 122.

Accordingly, in the de-bonding process of the step S07, since the adhesion of the first surface 121 is less than that of the second surface 122, which is different from the second embodiment, the separation interface is the first surface 121 between the de-bonding layer 12 and the rigid carrier plate 11 as shown in FIG. 4A, and the element substrate 1 a can be obtained thereby in FIG. 4B, including the element layer 16, the flexible substrate 14, the interface layer 15, the buffer layer 13 and the de-bonding layer 12.

Since the other technical features and processes of the manufacturing method of the element substrate of the third embodiment can be comprehended by referring to the second embodiment, they are not described here for conciseness.

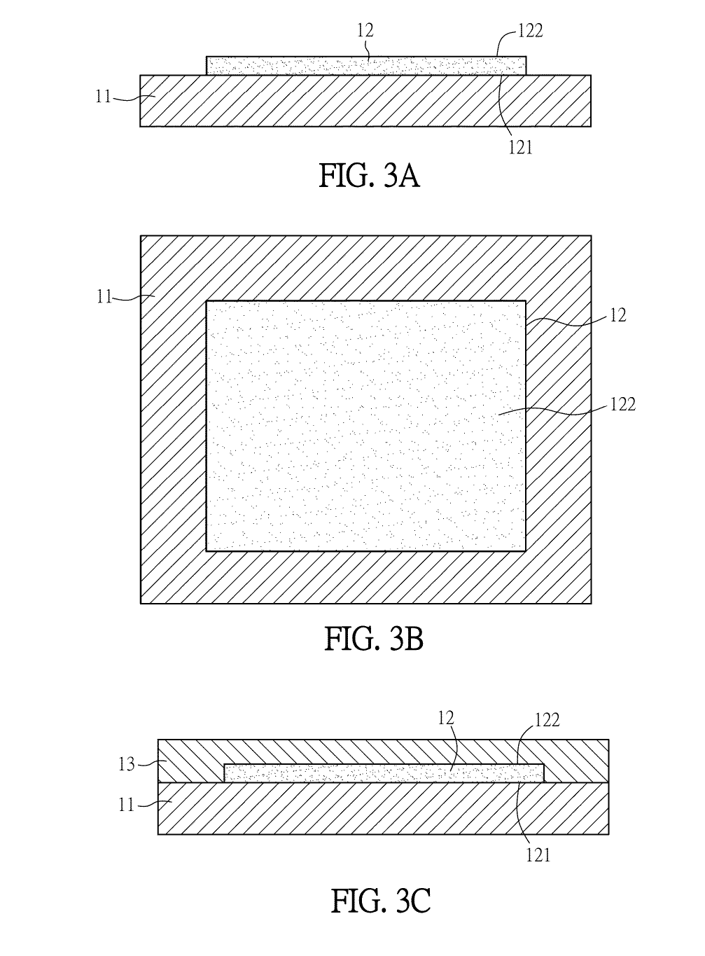

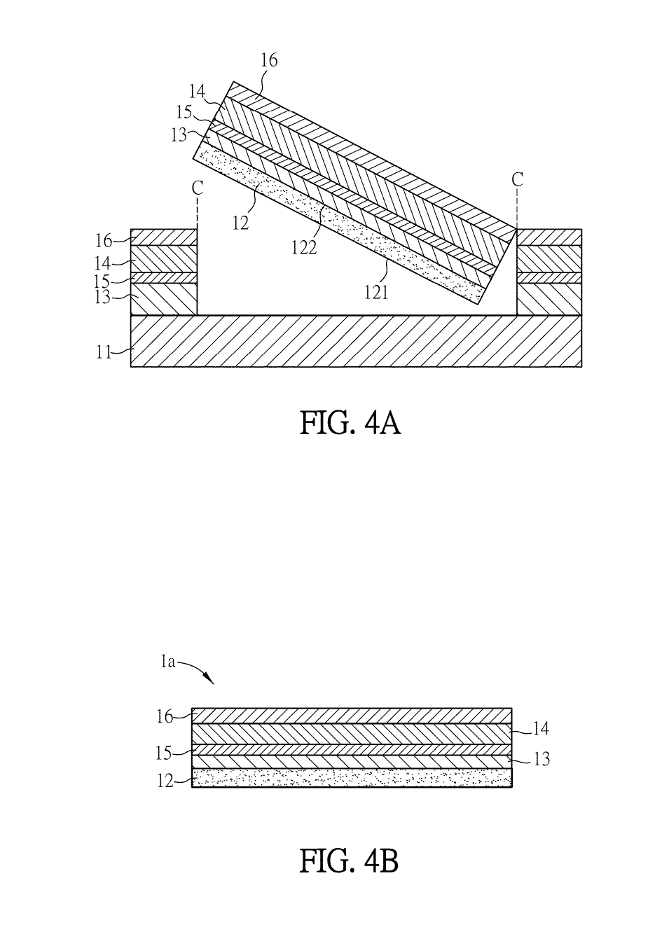

FIG. 5 is a schematic flow chart of a manufacturing method of an element substrate according to another embodiment of the invention, and FIGS. 6A to 6D are schematic diagrams of the manufacturing method of the element substrate according to the fourth embodiment of the invention.

Mainly different from the case of FIG. 1, the case of FIG. 5 is without the step S02. In other words, the main difference between the first and fourth embodiments is that the fourth embodiment is without the step S02, so the buffer layer is directly formed on the rigid carrier plate 11 as shown in FIG. 6B. Before forming the buffer layer 13, the surface of the rigid carrier plate 11 needs to be modified in property. The rigid carrier plate 11 has a surface 111. The surface 111 includes a first part P1 and a second part P2, and the second part P2 surrounds the first part P1. The adhesion of the surface 111 of the rigid carrier plate 11 needs to be adjusted so that the first part P1 has a lower adhesion than the second part P2. As an embodiment, the adhesion of the surface of the outer part (i.e. the second part P2) is made greater than that of the central part (i.e. the first part P1) by patterned UV illumination or plasma bombardment. Then, a buffer layer 13 is formed on the modified rigid carrier plate 11.

Since the steps S04 to S06 are similar to the foregoing embodiment, they are not described here again for conciseness. In the de-bonding process of the step S071, because the first part P1 of the surface 111 of the rigid carrier plate 11 has a lower adhesion than the second part P2, the element substrate 1 can be obtained by separating the buffer layer 13 from the rigid carrier plate 11 as shown in FIGS. 6C and 6D. Like the first embodiment, the element substrate 1 includes the element layer 16, the flexible substrate 14, the interface layer 15 and the buffer layer 13.

Since the other technical features and processes of the manufacturing method of the element substrate of the fourth embodiment can be comprehended by referring to the first embodiment, they are not described here for conciseness.

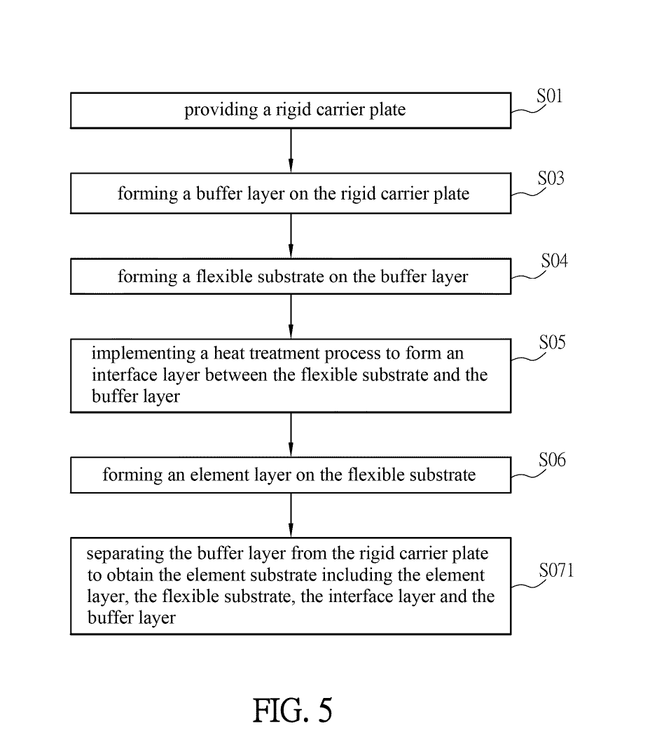

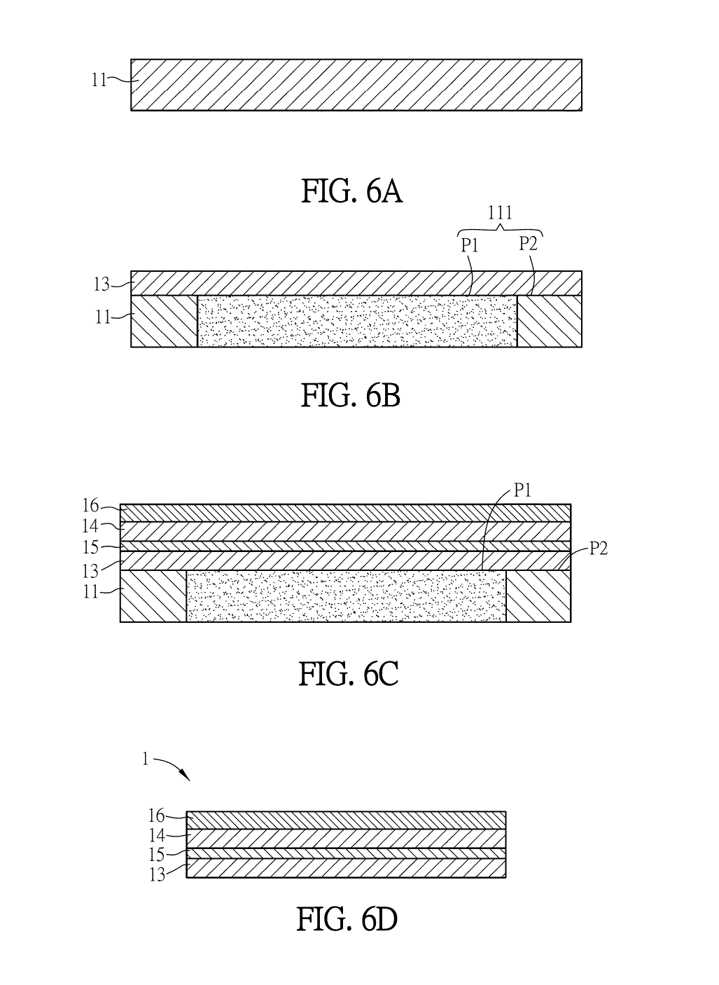

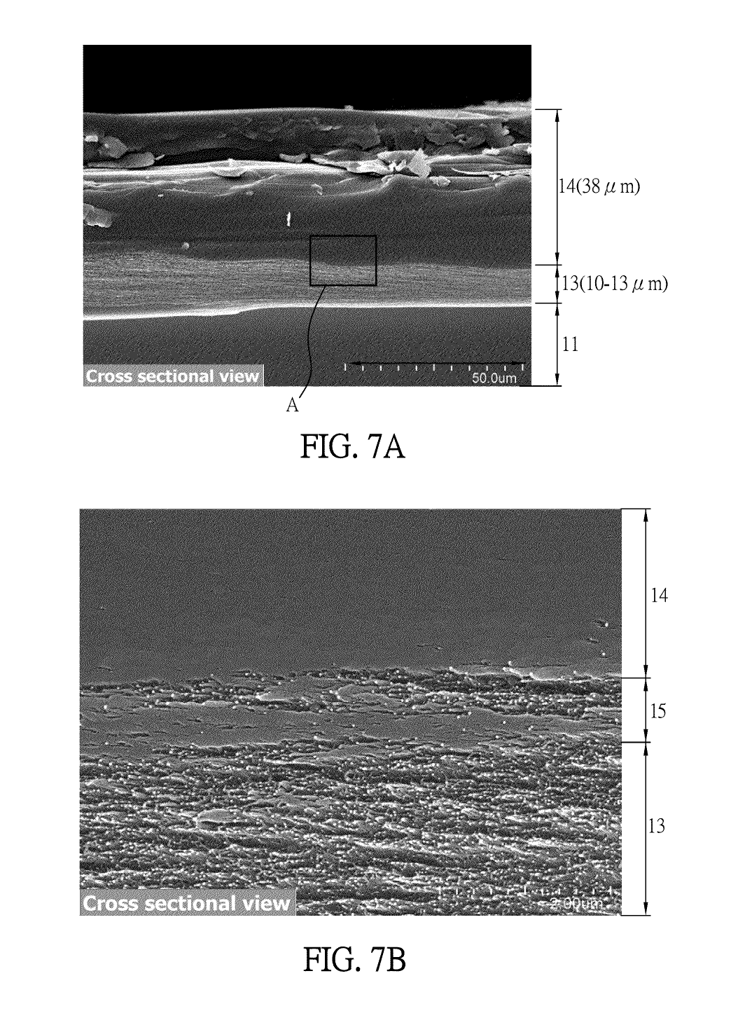

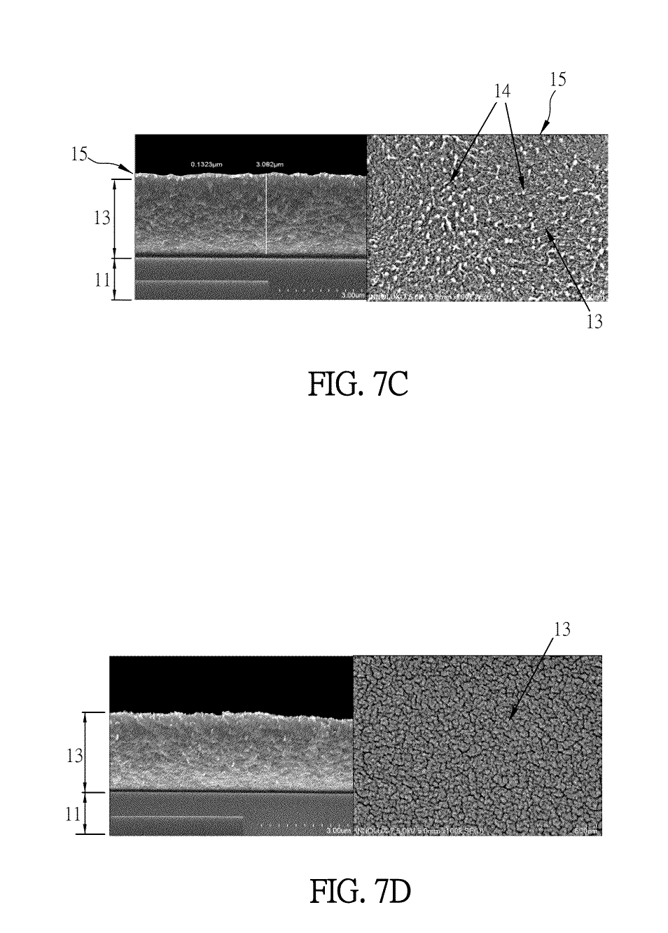

Moreover, by referring to the related SEM (scanning electron microscope) images, the evidence of the IPN generated between the flexible substrate 14 and the buffer layer 13 to form an interface layer 15 can be shown. FIGS. 7A to 7D are schematic SEM images according to the invention. FIG. 7A is a sectional diagram of the element substrate before the de-bonding, and FIG. 7B is an enlarged diagram of the region A in FIG. 7A. FIG. 7C shows the SEM image of the structure of FIG. 2F which undergoes the heat treatment but with the flexible substrate 14 removed by an external force, and FIG. 7D shows the SEM image of the buffer layer 13, the de-bonding layer 12 and the rigid carrier plate 11 which are not processed by heat treatment. Besides, the de-bonding layer 12 is not specifically shown in FIGS. 7A to 7D due to its thinness, and the interface layer 15 is also not shown in FIG. 7A.

It can be found from FIG. 7B that the IPN is generated between the flexible substrate 14 and the buffer layer 13 to form an interface layer 15. Besides, it can be found that the interface layer 15 includes partial material of both of the flexible substrate 14 and the buffer layer 13. In other words, the flexible substrate 14 and the buffer layer 13 dissolve and interpenetrate at their connection interface to form the interface layer 15 so as to have higher adhesion.

Moreover, the left parts of FIG. 7C and 7D are both sectional diagrams, the right part of FIG. 7C is the top view of the left part of FIG. 7C, and the right part of FIG. 7D is the top view of the left part of FIG. 7D. By comparing the right part of FIG. 7C and the right part of FIG. 7D, it can be found that the polymer network of the flexible substrate 14 (denoted by white color) and the polymer network of the buffer layer 13 (denoted by gray color) dissolve mutually and interpenetrate at the connection interface, giving the evidence that the IPN phenomenon exists.

A display apparatus of the invention includes the above-mentioned element substrate 1 or 1a. Since the structures of the element substrates 1 and 1a are clearly illustrated as above, they are not described here for conciseness. When the display apparatus is an LCD apparatus, the element substrate 1 or 1a can be a TFT substrate or a CF substrate. When the display apparatus is an OLED display apparatus, the element substrate 1 or 1a can be an OLED substrate. When the display apparatus is a touch panel, the element substrate 1 or 1a can be a touch substrate.

Summarily, in the element substrate, the display apparatus and the manufacturing method of the element substrate of the invention, the element substrate includes a flexible substrate, an element layer, a buffer layer and an interface layer, and the interface layer is formed between the flexible substrate and the buffer layer by a heat treatment process. Thereby, in comparison with the prior art, the invention is not limited to the type of the adhesive material and is capable of high heat-resistant property so as to be suitable for the high temperature process. Besides, the IPN phenomenon of the interface layer can make a better adhesion between the flexible substrate and the buffer layer, and therefore the electronic elements of the element substrate and the display apparatus can be made by a high temperature process so that the element substrate and the display apparatus can have better electric property and yield rate.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An element substrate, comprising:
a flexible substrate;
an element layer disposed on the flexible substrate;
a buffer layer disposed on the flexible substrate and disposed on the opposite sides of the flexible substrate with the element layer; and
an interface layer disposed between the flexible substrate and the buffer layer and including partial material of both of the flexible substrate and the buffer layer.

2. The element substrate as recited in claim 1, wherein the flexible substrate includes organic polymer material.

3. The element substrate as recited in claim 1, wherein the buffer layer includes polymer material of polyimide (PI), polyamic acid, acrylic or polysiloxane.

4. The element substrate as recited in claim 1, wherein the interface layer is formed by an interpenetrating polymer network (IPN).

5. The element substrate as recited in claim 1, further comprising:
a de-bonding layer disposed on the buffer layer.

6. A display apparatus, comprising:
an element substrate comprising:
a flexible substrate;
an element layer disposed on the flexible substrate;
a buffer layer disposed on the flexible substrate and disposed on the opposite sides of the flexible substrate with the element layer; and
an interface layer disposed between the flexible substrate and the buffer layer and including partial material of both of the flexible substrate and the buffer layer.

7. The display apparatus as recited in claim 6, wherein the flexible substrate includes organic polymer material and the buffer layer includes polymer material of polyimide (PI), polyamic acid, acrylic or polysiloxane.

8. The display apparatus as recited in claim 6, wherein the interface layer is formed by an interpenetrating polymer network (IPN).

9. The display apparatus as recited in claim 6, wherein the element substrate further comprising a de-bonding layer disposed on the buffer layer.

10. The display apparatus as recited in claim 6, wherein the element substrate is a thin film transistor (TFT) substrate, a color filter (CF) substrate, an organic light-emitting diode (OLED) substrate or a touch substrate.

11. A manufacturing method of an element substrate, comprising steps of:
providing a rigid carrier plate;
forming a buffer layer on the rigid carrier plate;
forming a flexible substrate on the buffer layer;
implementing a heat treatment process to form an interface layer between the flexible substrate and the buffer layer; and
forming an element layer on the flexible substrate.

12. The manufacturing method of an element substrate as recited in claim 11, before the step of forming the buffer layer, further comprising a step of:
forming a de-bonding layer on the rigid carrier plate.

13. The manufacturing method of an element substrate as recited in claim 12, further comprising a step of:
separating the de-bonding layer from the buffer layer to obtain the element substrate including the element layer, the flexible substrate, the interface layer and the buffer layer.

14. The manufacturing method of an element substrate as recited in claim 12, further comprising a step of:
separating the de-bonding layer from the rigid carrier plate to obtain the element substrate including the element layer, the flexible substrate, the interface layer, the buffer layer and the de-bonding layer.

15. The manufacturing method of an element substrate as recited in claim 11, further comprising a step of:
separating the buffer layer from the rigid carrier plate to obtain the element substrate including the element layer, the flexible substrate, the interface layer and the buffer layer.

16. The manufacturing method of an element substrate as recited in claim 13, before the step of forming the buffer layer wherein the de-bonding layer has a first surface facing the rigid carrier plate and a second surface which is opposite to the first surface and includes a first part and a second part surrounding the first part, further comprising a step of:
controlling the adhesion of the second surface of the de-bonding layer to make the adhesion of the first part lower than that of the second part.

17. The manufacturing method of an element substrate as recited in claim 13, before the step of forming the buffer layer wherein the de-bonding layer has a first surface facing the rigid carrier plate and a second surface opposite to the first surface, further comprising a step of:
controlling the adhesions of the first and second surfaces of the de-bonding layer to make the adhesion of the second surface lower than that of the first surface.

18. The manufacturing method of an element substrate as recited in claim 14, before the step of forming the buffer layer wherein the de-bonding layer has a first surface facing the rigid carrier plate and a second surface opposite to the first surface, further comprising a step of:
controlling the adhesions of the first and second surfaces of the de-bonding layer to make the adhesion of the first surface lower than that of the second surface.

19. The manufacturing method of an element substrate as recited in claim 15, before the step of forming the buffer layer wherein the rigid carrier plate has a surface including a first part and a second part surrounding the first part, further comprising a step of:
controlling the adhesion of the surface of the rigid carrier plate to make the adhesion of the first part lower than that of the second part.

20. The manufacturing method of an element substrate as recited in claim 11, wherein the interface layer is formed by an interpenetrating polymer network (IPN) generated after the heat treatment process with a subsequent cooling and includes partial material of both of the flexible substrate and the buffer layer.
